(19) United States
(12) Patent Application Publication
(10) Pub. No.: US 2026/0181790 A1
(43) Pub. Date: Jun. 25, 2026

(54) PROCESS AND APPARATUS FOR THE EVALUATION OF VALUABLE METALS IN ELECTRONIC SCRAP

(71) Applicant: Umicore, Brussels (BE)

(72) Inventors: Maarten SPRENGERS, Olen (BE); Joris LAUWERS, Olen (BE); Steven ART, Olen (BE)

(21) Appl. No.: 19/100,975

(22) PCT Filed: Aug. 4, 2023
(86) PCT No.: PCT/EP2023/071725

§ 371 Date: Feb. 4, 2025

(30) Foreign Application Priority Data
Aug. 9, 2022 (EP) 22189478.5

(51) Int. Cl. H05K 3/36; G06F 9/30; G06F 40/169; H05K 3/00

(52) U.S. Cl. CPC H05K 3/36; G06F 9/3016; G06F 40/169; H05K 3/0047

(57) ABSTRACT

This disclosure concerns the evaluation of a noble metal content in batches of materials such as electronic scrap, and in particular printed circuit boards, which is an essential initial step when recycling is envisaged. A process is presented comprising the steps of: —imaging at least a statistical representative number of the boards of the batch; —processing the images to detect the printed circuit boards; —for each detected printed circuit board, extracting a board-related feature vector using image processing technology; and, —providing a model taking at least the board-related feature vectors as input and calculating the noble metal content of the batch as output, wherein the model is calibrated against batch-level noble metal assays. The present application deals directly with batches of printed circuit boards, allowing for an approach wherein a regression model is calibrated based on total batch assays. Printed circuit board component assays are not needed.

The evaluation of the metal value in batches of materials such as electronic scrap is an essential preliminary step when recycling is envisaged.

In the present context, the electronic scrap of interest mainly consists of printed circuit boards (PCBs). Such electronic scrap is obtained in batches comprising hundreds of miscellaneous boards.

A highly accurate assay of each batch is needed for the commercial transaction between the provider of the materials and the recycler. An assay is also essential to closely monitor the metallurgical process, for example with regards to tracking any metal losses and optimizing process performance.

The value of electronic scrap is most often determined by the content of noble metals, i.e. the amount of PGMs (Ru, Rh, Pd, Os, Ir, Pt), Au and Ag present in the material.

Cu may also contribute significantly to the value and is in the present context also considered to be a noble metal.

Since most of these recycled materials are complex and inhomogeneous, the accurate and reliable determination of their composition can only be obtained by a 100% sampling scheme. This scheme is a rather complex multi-step process and includes a smelting operation performed on representative samples, thereby collecting the noble metals in a metallic phase, which is then again sampled for chemical analysis. These operations are time-consuming and lead to the delayed availability of crucial information about the exact content, which in return also delays the commercial transaction between provider and recycler.

An early evaluation or prediction of the noble metal content would therefore be advantageous, even if it is somewhat less precise than the chemical analysis.

A system has been developed towards this goal.

A publication dealing with a similar problem is “Material value estimation for recycling of waste printed circuit boards by deep-learning-assisted approach on X-ray images”, M. Firsching et al. SBSC 2022, 9^{th} Sensor-Based Sorting & Control, Shaker Verlag, Aachen 2022, pp. 161-178. This publication teaches a metal value estimation system for printed circuit boards. The estimation is based on a preliminary chemical assay of categories of components such as IC's, in particular Pin Grid Array and Ball Grid Array IC's, tantalum capacitors, and thickness measurements of gold coatings on connectors. Boards are subjected to automated component recognition and counting. The metal value of each board is derived from the component count in each category. The component assays are essential.

Contrasting with this, the present application deals directly with batches of printed circuit boards, allowing for a different approach, wherein a regression model is calibrated based on total batch assays. Component assays are not needed.

As explained above, complete batch assays are always needed and will always be performed, independently of any other estimation. By using these assays as calibration data, the delayed availability of accurate batch contents is greatly mitigated. Moreover, the fact that no extra effort is needed to obtain the calibration data renders continued calibration much more affordable.

A first embodiment of the invention concerns a process for evaluating a noble metal content of a batch of printed circuit boards, comprising the steps of:
imaging at least a statistical representative number of the printed circuit boards of the batch;
processing the images to detect the printed circuit boards;
for each detected printed circuit board, extracting a board-related feature vector using image processing technology; and,
providing a model taking at least the board-related feature vectors as input and calculating a noble metal content of the batch as output, wherein the model is calibrated against batch-level noble metal assays.

A batch generally corresponds to a collection of items obtained from a supplier in the framework of a single purchasing contract. In relation to the present invention, a batch may contain an arbitrary large number of printed circuit boards, some of which may be broken. It may also contain partially or fully detached individual components. In the context of the present invention, the term “board” is to be understood as “printed circuit board” or “PCB”, including all electronic or other components mounted on, or attached to, said board.

By detecting a board is meant that at least a corresponding bounding box is defined, which is preferably supplemented with a mask more precisely identifying the outline. This makes it possible to perform the board-related feature extraction.

The “imaging system” may be operated in the visible electromagnetic spectrum, but may also use IR, UV or X-ray sources and cameras.

Board-related features are for example the type of board, such as mother board or sound card, and the type of detected components on that board, such as IC's or connectors. The features are mathematically represented by a feature vector.

According to a further embodiment, the step of calculating the batch noble metal content is performed based on a combination of board-related feature vectors with batch-level features coming from sources other than printed circuit board imaging.

The board-related features are optionally combined with other batch-related features from sources not related to the board imaging, such as the identity of the supplier or the geographic origin of the batch. Also, historical data from batches coming from the same supplier may be used. A further example of a batch-related feature is the result of an alternative rapid analytical method performed on the batch or on a statistical representative sample of it. Prompt gamma neutron activation analysis is such a technique, which, when used on its own, would fail to provide the required accuracy.

According to a further embodiment, calculating the noble metal content of the batch is performed by either one of options (1) and (2):
(1) summing the board-related feature vectors, thereby obtaining a batch-related feature vector; calculating the batch noble metal content based on the batch-related feature vector; or,
(2) evaluating, for each printed circuit board, a printed circuit board noble metal content based on the board-related feature vector; summing the printed circuit board noble metal contents, thereby obtaining the batch noble metal content.

The first option can have advantages when non-linear regression models are used, as they will better capture complex interactions between batch and boards. Fitting a non-linear model will however need more calibration data. The second option provides for an evaluation of the noble metal content of individual boards, allowing for classification and sorting. While the prior art may achieve a similar result, it relies on a preliminary chemical assay of many different components to calibrate the model, while, according to this invention, total batch assays are used instead.

When using a linear model, both described options will calculate identical batch contents.

According to a further embodiment, the process of evaluating the nobel metal content is performed before metallurgically processing the batch for recovery of the noble metals.

Knowledge of the noble metal content, even if approximate, allows for the selection of an optimized metallurgical process. Noble metal rich batches could, for example, be processed with high priority, using a process ensuring a maximum yield of the nobel metals.

According to a further embodiment, the process of evaluating the noble metal content is used to define an advance payment to the supplier of the batch of the printed circuit boards.

Said advance payment corresponds to a preliminary evaluation of the noble metal contents using the above-described process. This payment is subject to regularization once a more precise content is determined.

According to a further embodiment, when selecting the noble metal content evaluation process according to above-mentioned option (2), the printed circuit boards are sorted into at least 2 classes based on the evaluated printed circuit board noble metal content.

According to a further embodiment, each printed circuit board class is individually metallurgically processed for recovery of the noble metals.

A batch may contain printed circuit boards having widely different noble metal contents. Separating them into at least 2 classes, differentiating boards with an expected higher noble metal content from boards with an expected lower noble metal content allows for the optimization of the ensuing metallurgical processes for the recovery and refining of the noble metals. The per-board metal contents will however only be evaluated if the calculation protocol according to the above-mentioned option (2) is applied.

According to a further embodiment, the batch-level noble metal assay is obtained by smelting a statistically representative sample of the batch, using an alloy as collector, which is analyzed.

A representative sample can be obtained by sampling the batch, followed by comminution of the sample, followed by re-sampling the comminuted product. This scheme of sampling, comminution, and re-sampling can be performed repeatedly, until a reduced sample volume is obtained that is compatible with the needs of the further steps leading to a chemical assay.

An advantageous further step is the smelting of the sample. The noble metals are hereby separated from less noble metals and concentrated in an alloy. Such an alloy is generally homogeneous and lends itself well to an accurate chemical assay. The assay can be performed using any accurate analytical method. Inductively coupled plasma (ICP) is for example a suitable technique.

According to a further embodiment, a total amount of combustible compounds of the batch is evaluated.

Combustible compounds in electronic scrap can comprise plastics and specific metals, in particular metallic aluminum. These compounds will significantly contribute to the enthalpy when a pyrometallurgical refining process is applied. It is thus useful to evaluate the approximate content of carbon and aluminum early-on, that is before the refining process is actually started.

This evaluation can be performed according to the same scheme as that applied to the noble metal evaluation. The model is then additionally calibrated against batch-level assays for carbon and aluminum.

A further embodiment concerns an apparatus for the evaluation of a noble metal content of a batch of printed circuit boards, configured to perform the above-mentioned process.

By apparatus “configured to perform” is meant that at least part of the software needed for performing the model is either present on, or made available to, said apparatus.

More in particular, an apparatus is disclosed comprising:
a transport belt suitable for exposing printed circuit boards to an imaging system;
the imaging system comprising at least one camera viewing the transport belt;
one or more computing units, connected to the imaging system and configured to perform the tasks of:
(a) processing images from the imaging system to detect the printed circuit boards;
(b) extracting a board-related feature vector for each detected printed circuit board;
(c) executing a model based on the vectors as input and calculating the noble metal content of the batch as output, wherein the model is calibrated against batch-level noble metal assays.

The computing units may comprise dedicated hardware, and/or one or more general purpose computers containing, or having access to, the software needed for executing the tasks. Some tasks may be performed by resources in the cloud.

A further embodiment concerns a computer program product comprising instructions which, when executed by a computer, cause the computer to perform the above-mentioned model.

A further embodiment concerns a data carrier comprising instructions which, when executed by a computer, cause the computer to perform the above-mentioned model.

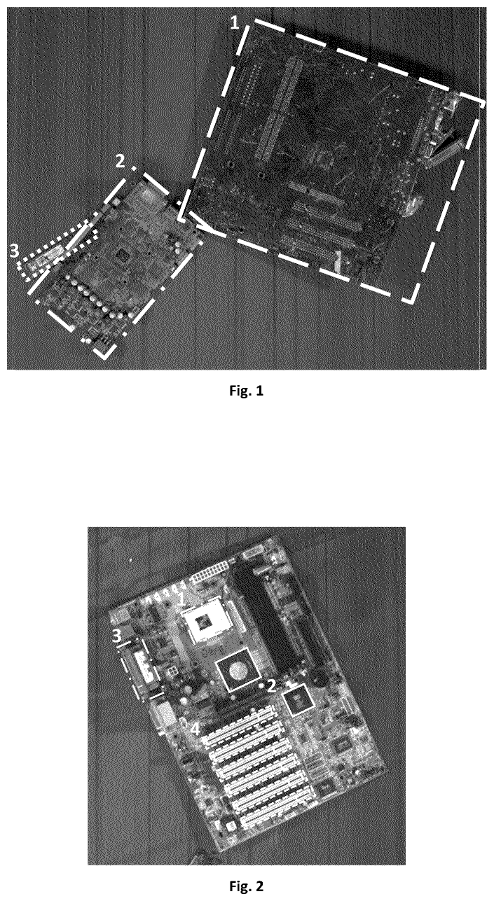

The following example is provided to further illustrate the present invention. FIGS. 1 to 4 refer to the following aspects.

FIG. 1 illustrates the imaging and detection of PCBs on a transport belt. Reference 1 corresponds to the backside of a computer motherboard, reference 2 to the frontside of a soundcard, reference 3 to the frontside of a RAM memory card.

FIG. 2 illustrates the extraction of board-related features from an imaged motherboard frontside. Reference 1 is a CPU, reference 2 is a chipset IC, reference 3 is a parallel port, reference 4 is a PCI slot.

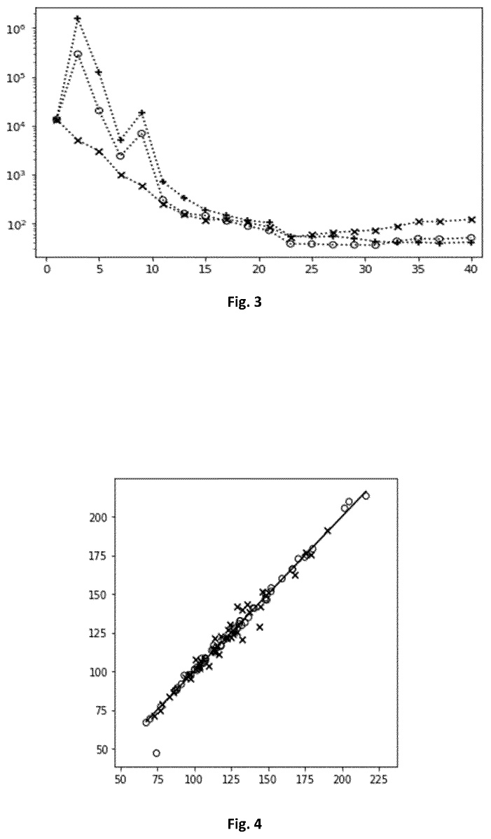

FIG. 3 shows on the y-axis the average mean squared error (MSE) of Au for 10 different training scenarios expressed in ppm versus the number of training batches on the x-axis. Three linear models are fitted using a common least squares method (x), Lasso (+), and Ridge penalization (o).

FIG. 4 shows predicted (x) and training (o) results of the Lasso regression for Au. The y-axis is the predicted Au concentration in ppm and the x-axis is the true/simulated Au concentration. One marker represents one batch. The continuous line represents an ideal response where the predicted value equals the true value.

To illustrate the invention, a realistic simulation is used of a variety of printed circuit boards, accurately representing those typically encountered in the e-waste recycling industry. A database of components and of boards populated with these components, is created. Simulated batches of boards are then generated, each batch having an associated total noble metal content. Finally, an optical recognition system is simulated, including the typical errors to be accounted for in a real process.

The regression model is fitted or trained, to correlate the recognized features with the noble metal content of each batch.

### Component Database

25 component types are defined. Each component type is characterized by a mean value, which is randomly chosen between 5 and 50 g for the component weight, and between 5 and 1000 mg for the noble metal content, for each of Ag, Pd and Au. For each generated component, a normal distribution for the weight and for the noble metal content is applied. The standard deviation is set to 25% for the weight, 30% for Ag, 35% for Pd, and 25% for Au. Each individual component is therefore unique in its type, weight and composition. An offset with a normal distribution with a relative standard deviation of 10% is applied to each batch, with respect to the component's metal concentration.

### Board Database

10 board types are defined. Each board type is characterized by a board weight distribution and a maximum allowed count of each type of component. For each generated board, the number of components of each type are randomly chosen from 0 to the allowed maximum. The board weight per type is characterized by a normal distribution with a randomly chosen average weight between 100 g and 1000 g. The relative standard deviation is 25%. A bias is applied to the average weight for every type within a batch by multiplying it with a random number out of a normal distribution with a mean of 100% and a standard deviation of 10%. Each individual board is therefore unique in its type, number and selection of components, composition and weight. The component and board databases closely mimic industrial reality.

### Simulated Batches of Boards

100 batches of boards are generated. Each batch consists of a randomly selected subset of on average 5 board types out of the 10 available, with, for each selected type, a random number of boards between 0 and 1000. On average, each batch thus comprises 2500 unique boards.

### Optical Recognition of Boards and Components

In the simulation, a board type has a 90% probability of getting both correctly detected and typed, also recognizing if a board is presented upside-down. A 5% probability of being wrongly typed, and a 5% probability of not getting detected at all, is built in the simulation. There is a 50% probability for a board to be presented upside-down, in which case the board type is detectable, while the components are not.

Components have a 95% probability of getting detected and typed when a correctly oriented board is presented, whether or not the board is correctly typed. There is a 2.5% probability of not detecting a component, and a 2.5% probability of wrongly typing a component.

The above parameters are derived from our experience with a camera-based feature detection with Mask R-CNN (“Mask R-CNN”, K. He, G. Gkioxari, P. Doller and R. Girshick, 2017 IEEE International Conference on Computer Vision (ICCV), 2017, pp. 2980-2988) on boards moving on a conveyor belt. Mask R-CNN was trained on board and component annotations. Python was used as programming language and TensorFlow, Keras and imgaug to create and train the neural network. Pre- and post-processing of the images and results was performed with a combination of the following packages: sci-kit image, PILLOW, sci-kit learn, scipy, numpy. Pre-processing steps consist of resizing the image and normalizing the color channels. Post-processing steps are image stitching and “non-maximum suppression” to count boards and components only once.

FIGS. 1 and 2 provide a typical example of the picture recorded by the camera. Boards occasionally overlap and may be seen upside down half of the time. The machine learning model mask R-CNN was used to detect the type, orientation and mask of a board and component. The mask of the boards and components are used to link them to each other. Metadata can be added, such as broken or partially covered boards, board color, area, etc.

### Regression Model

The fitting/training process is performed on the simulated batches. For each board and for each component, a feature vector is derived. The feature vectors are aggregated over the full batch and this aggregated vector is used in a regression model aiming at predicting the noble metal content of that batch. A linear regression model is fitted using the methods of least squares, Lasso, and ridge penalization. The Lasso regression was slightly better than the Ridge regression and outperformed the least squares method with an increasing number of training batches. The least squares method is sensitive to the existing cross correlations in the dataset.

### Results

Using this scheme, it is shown in FIG. 3 that a meaningful prediction of the noble metal content can be achieved after training on about 30 batches. This is remarkably fast in view of the many different boards and components involved. It is believed that this efficiency is due to cross-correlations existing between the board types and the components mounted on them. Such cross-correlations are implied by the statistics used when creating the synthetic batches. These same cross-correlations are believed to be present in industrial reality.

The accuracy of the noble metal prediction is shown in FIG. 4. This result is more than adequate for the purpose of providing an early feedback on the material composition to the supplier of the batch, resulting e.g. in a faster payout, or for planning the further processing of the materials without having to await the results of a precise chemical assay.

Once such a system is actually exploited, the training database can easily be completed with the actual data of each batch, thus strengthening the correlation between feature vectors and chemical assays. A self-learning system is then obtained, without the need for any additional expenses or efforts other than running the fitting or training algorithm of the regression model regularly.

This achievement is particularly relevant, as a major e-waste recycler may handle several batches per day.

1-12. (canceled)

13. A process for evaluating a noble metal content of a batch of printed circuit boards, comprising the steps of:
imaging at least a statistical representative number of the printed circuit boards of the batch;
processing the images to detect the printed circuit boards;
for each detected printed circuit board, extracting a board-related feature vector using image processing technology; and,
providing a model taking at least the board-related feature vectors as input and calculating the noble metal content of the batch as output, wherein the model is calibrated against batch-level noble metal assays, and, wherein the batch-level noble metal assays are obtained by smelting a statistically representative sample of the batch, using an alloy as collector, which is analyzed.

14. The process according to claim 13, wherein the batch noble metal content is calculated based on a combination of board-related feature vectors with batch-level features coming from sources other than printed circuit board imaging.

15. The process according to claim 13, wherein calculating the noble metal content of the batch is performed by one of options (1) or (2):
(1) summing the board-related feature vectors, thereby obtaining a batch-related feature vector; calculating the batch noble metal content based on the batch-related feature vector; or,
(2) evaluating, for each printed circuit board, a printed circuit board noble metal content based on the board-related feature vector; summing the printed circuit board noble metal contents, thereby obtaining the batch noble metal content.

16. The process according to claim 13, wherein evaluating the nobel metal content is performed before metallurgically processing the batch for recovery of the noble metals.

17. The process according to claim 15 option (2), wherein the printed circuit boards are sorted into at least 2 classes based on the evaluated printed circuit board noble metal content.

18. The process according to claim 17, wherein each printed circuit board class is individually metallurgically processed for recovery of the noble metals.

19. The process according to claim 13, wherein a total amount of combustible compounds of the batch is evaluated.

20. An apparatus for the evaluation of a noble metal content of a batch of printed circuit boards, configured to perform the process according to claim 13, wherein the apparatus comprises:
a transport belt suitable for exposing printed circuit boards to an imaging system;
the imaging system comprising at least one camera viewing the transport belt;
one or more computing units, connected to the imaging system and configured to perform the tasks of:
(a) processing images from the imaging system to detect the printed circuit boards;
(b) extracting a board-related feature vector for each detected printed circuit board;
(c) executing a model based on the vectors as input and calculating the noble metal content of the batch as output, wherein the model is calibrated against batch-level noble metal assays.

21. A computer program product comprising instructions which, when executed by a computer, causes the computer to perform the model according to the process of claim 13.
